(19) United States
(12) Patent Application Publication
(10) Pub. No.: US 2008/0054471 A1
(43) Pub. Date: Mar. 6, 2008

(54) Semiconductor Device and Fabricating Method Thereof

(76) Inventors: CHEON MAN SHIM, Yeongdeungpo-gu (KR); Sang Chul Kim, Yeongdeungpo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/846,689

(22) Filed: Aug. 29, 2007

(30) Foreign Application Priority Data
Aug. 29, 2006 (KR) 10-2006-0082438

(51) Int. Cl. H01L 21/4763; H01L 23/48

(52) U.S. Cl. 257/760; 438/624; 257/E21.579; 257/E23.168

(57) ABSTRACT

A semiconductor device according to an embodiment includes a first metal wiring formed on a semiconductor substrate; a first dielectric barrier layer formed on the first metal wiring; an inter-layer dielectric (ILD) layer formed on the first dielectric barrier layer; a plurality of second metal wirings formed on the ILD layer; and at least one hole formed in the ILD layer in regions between second metal wirings.

### CROSS-REFERENCE TO RELATED APPLICATION

The present application claims the benefit under 35 U.S.C. §119 of Korean Patent Application No. 10-2006-0082438, filed Aug. 29, 2006, which is hereby incorporated by reference in its entirety.

### BACKGROUND

In a semiconductor device, in order to reduce RC delay, copper (Cu) has been used as the metal for forming wiring, and dielectric material with a low-k value has been used as an inter-layer dielectric (ILD). Normally, the dielectric material with a k-value of less than 3 is used for the ILD and efforts for reducing the k-value have been progressed.

### BRIEF SUMMARY

Embodiments of the present invention can indicate the property of an ultra low-k value between wirings having a narrow gap. Also, a semiconductor device and a fabricating method thereof are provided capable of improving the property of the device and the yield of the product through forming a dielectric layer having a good mechanical strength.

The semiconductor device according to an embodiment includes a first metal wiring formed on a semiconductor substrate; a first dielectric barrier layer formed on the first metal wiring; an inter-layer dielectric (ILD) layer formed on the first dielectric barrier layer; a plurality of second metal wirings formed on the ILD layer; and at least one hole formed in the ILD layer.

Also, a fabricating method of the semiconductor device according to an embodiment includes: forming a first metal wiring on a semiconductor substrate; forming a first dielectric barrier layer on the first metal wiring; forming an inter-layer dielectric (ILD) layer on the first dielectric barrier layer; forming a plurality of second metal wirings on the ILD layer; and forming at least one hole in the ILD layer.

### BRIEF DESCRIPTION OF THE DRAWINGS

FIGS. 1 and 2 are views for explaining a fabricating method of a semiconductor device according to an embodiment of the present invention.

FIGS. 3 and 4 are views showing a shape of a hole formed in the semiconductor device according to embodiments of the present invention.

### DETAILED DESCRIPTION

Embodiments of the present invention will be described in detail with reference to accompanying drawings.

In the description of embodiments, when a layer (film) or structure is described as being formed “on/above/over/upper” or “down/below/under/lower” another layer or structure, it can be understood as directly contacting the other layer or structure, or additional layers or structures can be formed therebetween. Therefore, the meanings should be judged according to the technical idea of the embodiment.

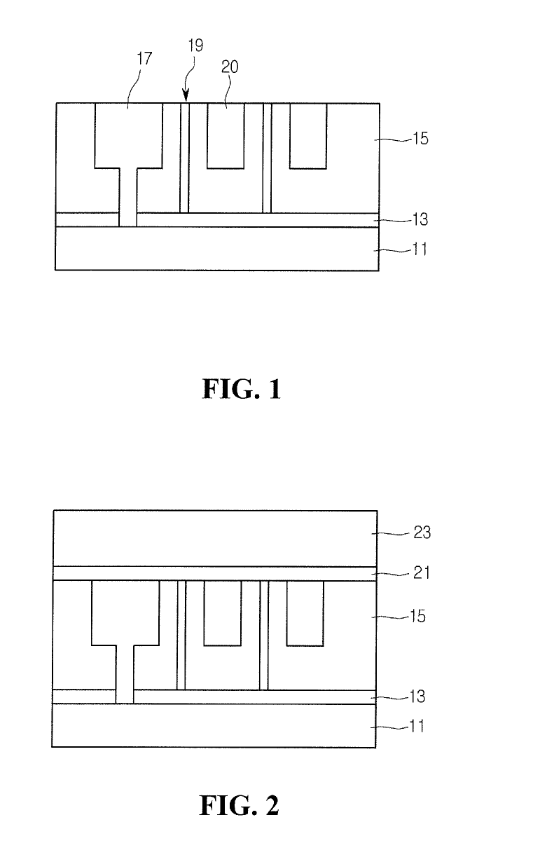

FIGS. 1 and 2 are views for explaining a fabricating method of a semiconductor device according to an embodiment.

Referring to FIGS. 1 and 2, a first barrier layer 13 can be formed on a metal wiring 11. The metal wiring 11 can be formed on a semiconductor substrate.

The metal wiring 11 can be formed of copper (Cu), and the first dielectric barrier layer 13 can be formed of a material with a low-k. For example, the first dielectric layer 13 can be formed of a material with a k-value less than 3.

A first inter-layer dielectric (ILD) layer 15 can be formed on the first dielectric barrier layer 13.

Then, a first wiring 17 is formed to be connected to the metal wiring 11 by penetrating through the first ILD layer 15 and the first dielectric barrier layer 13. In addition, second wiring 20 is formed on the first ILD layer 15. The first wiring 17 can perform the function of connecting the metal wiring 11 to an upper metal wiring that is formed later.

The first wiring 17 and the second wiring 20 can be formed by means of various processes, for example, the first wiring 17 can be formed by a damascene process. The processes forming the first wiring 17 and the second wiring 20 are well-known in the art so that detailed description thereof will be omitted herein.

Subsequently, at least one hole 19 is formed in the first ILD layer 15. The hole 19 is formed directed downward from the surface of the first ILD layer 15. Also, the hole 19 can be formed between the first wirings 17, between the second wirings 20 or between the first wiring 17 and the second wiring 20. The hole 19 can be selectively formed in the ILD layer 15 where a wiring gap is narrow.

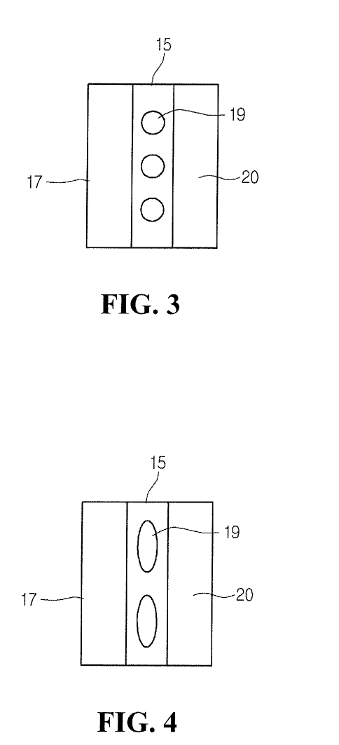

The surface of a hole 19 formed in the first ILD layer 15 can be formed in any one shape or a combination of shapes of a circle, an oval, and a polygon. FIGS. 3 and 4 are views showing a shape of a hole formed in the semiconductor device according to embodiments. The shape of a diameter of length of the surface shape of the hole formed in the first ILD layer 15 can be formed at size of 1 to 10000 nm.

With the fabricating method of the semiconductor device according to an embodiment, the hole 19 can be formed in various shapes such as a circle, an oval, and a polygon. Also, the size of the hole 19 can be variously formed, if desired. The density of the first ILD layer 15 can be adjusted by adjusting the number and shape of the holes 19.

As such, using the plurality of holes 19 formed in the first ILD layer 15, the k-value of the first ILD layer 15 can be reduced. That is, the k-value of the first ILD layer 15 can become small in proportion to the number of holes 19 produced in the first ILD layer 15. This can be implemented by forming a hole 19 to have an empty space, or air pocket, therein.

Therefore, according to embodiments of the present invention, the k-value of the first ILD layer 15 can be adjusted by adjusting the size and number of holes 19. In addition, the value of capacitance formed between the metal layers can be reduced by forming the first ILD layer 15 with holes 19 to form a porous layer with the low-k value. Accordingly, RC delay can be reduced and the value of the RC delay can be controlled.

The hole 19 can be formed in the first ILD layer 15 after a chemical mechanical polishing (CMP) process for forming the first wiring 17. In particular, the formation of the first wiring 17 is completed by the CMP process for the formation of the wiring, after a metal layer for the formation of the first wiring 17 is deposited on the first ILD layer 15. The second wiring 20 can be simultaneously formed by the process to form the first wiring 17.

Because the CMP process is performed with reference to the first ILD layer 15 in which the hole 19 is not yet formed, the CMP process can be performed in a mechanically stable state.

Also, since the material with the low-k supports the area where a pattern is not formed, even in a subsequent CMP process for the formation of an additional upper wiring after forming the hole 19, the subsequent CMP process can be easily performed, as compared to the case where an ultra low dielectric material is used.

In an embodiment, the hole 19 can be formed by means of an etching process for the first ILD layer 15.

Then, referring to FIG. 2, a second dielectric barrier layer 21 can be formed on the first ILD layer 15 having the hole 19. The second dielectric barrier layer 21 can be formed for example, by means of a PECVD (plasma enhanced chemical vapor deposition) method or a CVD method. In the case where the second dielectric barrier layer 21 is formed by means of such a method, the hole 19 can be formed to have an empty space therein.

Then, a second ILD layer 23 can be formed on the second dielectric barrier layer 21. The process for the formation of the first wiring can be performed in the second ILD layer 23 as needed, and a plurality of holes can be also formed in the second ILD layer 23.

As described above, the semiconductor device according to an embodiment includes a metal wiring 11 formed on a semiconductor substrate, a first dielectric barrier layer 13 formed on the first metal wiring 11, an ILD layer 15 formed on the first dielectric barrier layer 13, and at least one hole 19 formed in the ILD layer 15.

In addition, the semiconductor device can further include a first wiring 17 connected to the metal wiring 11 penetrating through the first ILD layer 15 and the first dielectric barrier layer 13, a second dielectric barrier layer 21 formed on the first ILD layer 15, and a second ILD layer 23 formed on the second dielectric barrier layer 21.

The metal wiring 11 can be formed of Cu, and the first dielectric barrier layer 13 can be formed of a material with a low-k.

A plurality of first wirings 17 and second wirings 20 can be formed, and a hole 19 can be formed between the first wirings 17, between the second wirings 20, and/or between the first wiring 17 and the second wiring 20.

The hole 19 is formed to have an empty space therein, and the surface of the hole 19 can be formed in any one shape of a circle, an oval, and a polygon. In various embodiments, the surface of the hole can be formed in the first ILD layer 15 at the size of 1 to 10000 nm. The hole can be formed between the first dielectric barrier layer 13 and the second dielectric barrier layer 21.

With the semiconductor device and the fabricating method thereof according to an embodiment, a device having a porous dielectric property can be easily formed, and a CMP process can also be performed on a mechanically stable dielectric. Also, embodiments have an advantage where it is not necessary to purchase a separate equipment for forming the porous dielectric. In particular, the holes 19 can be formed in the ILD layer as needed.

In addition, the property of the device and the yield of the product can be improved by forming a dielectric layer having a good mechanical strength in a fabrication process while having an ultra low-k value in a necessary portion.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a first metal wiring formed on a semiconductor substrate;
a first dielectric barrier layer formed on the first metal wiring;
an inter-layer dielectric (ILD) layer formed on the first dielectric barrier layer;
a plurality of second metal wirings formed on the ILD layer; and
at least one hole formed in the ILD layer.

2. The semiconductor device according to claim 1, wherein the plurality of second metal wiring comprises copper (Cu), and the first dielectric barrier layer comprises a material with a low-k.

3. The semiconductor device according to claim 1, wherein the at least one hole is formed between adjacent second metal wirings of the plurality of second metal wirings.

4. The semiconductor device according to claim 1, wherein the surface shape of the at least one hole formed in the ILD layer is at least one shape selected from the group consisting of a circle, an oval, and a polygon.

5. The semiconductor device according to claim 1, wherein a diameter or length of the surface shape of the at least one hole formed in the ILD layer is formed at size of 1 to 10000 nm.

6. The semiconductor device according to claim 1, further comprising a second dielectric barrier layer formed on the ILD layer.

7. The semiconductor device according to claim 6, wherein the at least one hole is formed between the first dielectric barrier layer and the second dielectric barrier layer.

8. The semiconductor device according to claim 1, wherein the at least one hole is formed to have an empty space therein.

9. A fabricating method of a semiconductor device comprising the steps of:
forming a first metal wiring on a semiconductor substrate;
forming a first dielectric barrier layer on the first metal wiring;
forming an inter-layer dielectric (ILD) layer on the first dielectric barrier layer;
forming a plurality of second metal wirings on the ILD layer; and
forming at least one hole in the ILD layer.

10. The method according to claim 9, wherein the second metal wiring comprises copper (Cu), and the first dielectric barrier layer comprises a material with a low-k.

11. The method according to claim 9, wherein the at least one hole is formed between adjacent second metal wirings of the plurality of second metal wirings.

12. The method according to claim 9, wherein the surface shape of the at least one hole formed in the ILD layer is at least one shape selected from the group consisting of a circle, an oval, and a polygon.

13. The method according to claim 9, wherein a diameter or length of the surface shape of the at least one hole formed in the ILD layer is formed at size of 1 to 10000 nm.

14. The method according to claim 9, further comprising forming a second dielectric barrier layer on the ILD layer.

15. The method according to claim 14, wherein the at least one hole is formed between the first dielectric barrier layer and the second dielectric barrier layer.

16. The method according to claim 9, wherein the at least one hole is formed to have an empty space therein.

17. The method according to claim 9, wherein forming the plurality of second metal wirings comprises performing a damascene process.

18. The method according to claim 9,
wherein forming the plurality of second metal wirings comprises:
patterning and etching the ILD layer;
depositing metal on the etched ILD layer; and
performing a chemical mechanical polishing (CMP) process until a top surface of the ILD layer is exposed,
wherein the at least one hole is formed in the ILD after the CMP process.

19. The method according to claim 9, wherein forming the at least one hole comprises performing an etching process.
